(19) United States
(12) Patent Application Publication
(10) Pub. No.: US 2026/0006926 A1
(43) Pub. Date: Jan. 1, 2026

(54) Color mosaic filter layouts for enhanced camera performance

(71) Applicant: APPLE INC., Cupertino, CA (US)

(72) Inventors: Shay Yosub, Kfar Yehezkel (IL); Niv Gilboa, Tel Aviv (IL); Assaf Avraham, Givatayim (IL); Gilad Michael, Sunnyvale, CA (US)

(21) Appl. No.: 19/062,070

(22) Filed: Feb. 25, 2025

Related U.S. Application Data
(60) Provisional application No. 63/665,828, filed on Jun. 28, 2024.

(51) Int. Cl. H10F 39/00; H04N 25/704; H04N 25/78

(52) U.S. Cl. CPC H10F 39/8053; H04N 25/704; H04N 25/78; H10F 39/8063

(57) ABSTRACT

An image sensing device includes a semiconductor substrate on which a first array of photodetectors is disposed. Readout circuits are disposed on the substrate and coupled to respective pairs of the photodetectors, and output signals from the respective pairs in a first mode, in which the signals are read out individually from each of the photodetectors, and in a second mode, in which the signals are binned together pairwise. A color filter layer disposed over the photodetectors includes a matrix of red, green, and blue tiles, such that in a first set of the pairs of the photodetectors, both the photodetectors are overlain by respective green tiles, while in a second set of the pairs of the photodetectors, one of the photodetectors is overlain by a first tile of a first color, while the other one of the photodetectors is overlain by a second tile of a different, second color.

### CROSS-REFERENCE TO RELATED APPLICATION

This application claims the benefit of U.S. Provisional Patent Application 63/665,828, filed Jun. 28, 2024, which is incorporated herein by reference.

### FIELD

The present invention relates generally to image sensing arrays and particularly to arrays including color mosaic filters and methods for their fabrication and use.

### BACKGROUND

Camera systems use autofocus (AF) in many applications to ensure that relevant portions of scenes, at varying distances from the camera, are acquired in sharp focus. Some autofocus systems use image information output by the image sensor of the camera in estimating the optimal distance of the image sensor from the camera lens. On-board electromechanical components then drive the lens position to the optimal distance from the image sensor.

To improve autofocus performance, some cameras use dual-pixel autofocus, and particularly phase difference-based autofocus, based on signals output by special pixels in the image sensing array that are divided into two sub-pixels. These special pixels can be created, for example, by fabricating a metal shield over certain pixels in such a way as to obscure one half of the sensing area of each such pixel. Phase-difference autofocus logic compares the outputs of the divided sub-pixels in order to estimate whether the image is in focus, and thus provides feedback in order to drive the lens to converge rapidly to a position at which the image is in focus.

U.S. Pat. No. 11,563,910, whose disclosure is incorporated herein by reference, describes an image capture device including an array of pixels. Each pixel includes a 2×2 array of photodetectors. The image capture device also includes an array of 1×2 on-chip lenses (OCLs) disposed over the array of pixels, in a manner that is said to improve phase detection autofocus (PDAF).

U.S. Patent Application Publication 2023/0090827, whose disclosure is incorporated herein by reference, describes image capture devices that includes an array of pixels, each pixel including a photodetector. A Bayer pattern color filter is disposed over a 4×4 subset of pixels in the array of pixels. The Bayer pattern color filter defines a first 2×2 subset of pixels sensitive to red light; a second 2×2 subset of pixels sensitive to green light; a third 2×2 subset of pixels sensitive to green light; and a fourth 2×2 subset of pixels sensitive to blue light. A set of OCLs is disposed over the pixels, including 1×1, 1×2, and 2×2 OCLs in different embodiments.

In the present description and in the claims, the terms “light” and “optical radiation” are used interchangeably to refer to electromagnetic radiation in any of the visible, infrared, and ultraviolet spectral ranges.

### SUMMARY

Embodiments of the present invention that are described hereinbelow provide improved image sensing arrays and image capture devices.

There is therefore provided, in accordance with an embodiment of the invention, an image sensing device, including a semiconductor substrate and a first array of photodetectors disposed on the substrate. Readout circuits, are disposed on the substrate and coupled to respective pairs of the photodetectors, and are configured to output signals from the respective pairs in a first mode, in which the signals are read out individually from each of the photodetectors, and in a second mode, in which the signals are binned together pairwise. A color filter layer disposed over the photodetectors includes a matrix of red, green, and blue tiles, such that in a first set of the pairs of the photodetectors, both the photodetectors are overlain by respective green tiles, while in a second set of the pairs of the photodetectors, one of the photodetectors is overlain by a first tile of a first color, while the other one of the photodetectors is overlain by a second tile of a different, second color.

In some embodiment, the device includes first microlenses overlying respective pairs of the photodetectors in the first set, and second microlenses overlying the photodetectors in the second set. In a disclosed embodiment, the pairs of the photodetectors in the first set define phase detection autofocus (PDAF) pixels, and the readout circuits are configured to output a difference between the signals output by the photodetectors in the pairs in the first set. In one embodiment, the second microlenses overlie respective pairs of the photodetectors in the second set. Alternatively, each of the second microlenses overlies a single, respective one of the photodetectors.

In one embodiment, in at least some of the pairs in the second set, one of the photodetectors is overlain by a red tile, while the other one of the photodetectors is overlain by a blue tile. Alternatively or additionally, in at least some of the pairs in the second set, one of the photodetectors is overlain by a red or blue tile, while the other one of the photodetectors is overlain by a green tile.

In disclosed embodiments, the green tiles cumulatively cover more than 50% of a total area of the color filter layer or even at least 75% of the total area of the color filter layer.

Additionally or alternatively, the first and second sets of the pairs of the photodetectors are interleaved on the substrate in a grid pattern.

There is also provided, in accordance with an embodiment of the invention, an image sensing device, including semiconductor substrate and an array of photodetectors disposed on the substrate. A color filter layer disposed over the photodetectors includes a matrix of red, green, and blue tiles, such that the green tiles cumulatively cover more than 50% of a total area of the color filter layer.

In a disclosed embodiment, the green tiles cumulatively cover at least 75% of the total area of the color filter layer.

In some embodiments, the device includes an arrangement of microlenses disposed over the color filter layer, including first microlenses, which have a first transverse dimension no greater than a pitch of the array of photodetectors and are disposed respectively over all the photodetectors that are covered by the green tiles, and second microlenses, which have a second transverse dimension greater than the pitch disposed over the photodetectors that are covered by the red and blue tiles, each second microlens being configured to focus light onto two or more of the photodetectors. In a disclosed embodiment, the two or more of the photodetectors onto which the second microlenses focus the light define phase detection autofocus (PDAF) pixels.

There is also provided, in accordance with an embodiment of the invention, a method for image sensing, which includes coupling readout circuits to respective pairs of photodetectors in a first array disposed on a semiconductor substrate. The readout circuits output signals from the respective pairs in a first mode, in which the signals are read out individually from each of the photodetectors, and in a second mode, in which the signals are binned together pairwise. The photodetectors are overlaid with a color filter layer including a matrix of red, green, and blue tiles, such that in a first set of the pairs of the photodetectors, both the photodetectors are overlain by respective green tiles, while in a second set of the pairs of the photodetectors, one of the photodetectors is overlain by a first tile of a first color, while the other one of the photodetectors is overlain by a second tile of a different, second color.

### BRIEF DESCRIPTION OF THE DRAWINGS

The present invention will be more fully understood from the following detailed description of the embodiments thereof, taken together with the drawings in which:

FIG. 1 is a schematic side view of a camera comprising an image sensing device with a novel mosaic filter layout, in accordance with an embodiment of the invention; and

FIGS. 2, 3, 4, 5, 6, 7, 8 and 9 are schematic partial frontal views of image sensing devices, in accordance with embodiments of the invention.

### DETAILED DESCRIPTION

Traditional Bayer-type color image sensors comprise an array of photodetectors overlaid with a color filter layer comprising a matrix of red, green, and blue tiles with the same pitch as the photodetector array, i.e., each color tile in the matrix covers a single photodetector. (The term “tile” is used in the present description and in the claims to refer to a contiguous region of a single color within the color filter layer, while a pattern of interleaved tiles or other elements of different colors is referred to as a “mosaic.”) For improved resolution and low-light performance (by binning together the signals from adjacent detectors), in some image sensors each colored tile in the color filter layer overlies a group of two or more photodetectors. This sort of arrangement is described in the above-mentioned U.S. Pat. No. 11,563,910 and U.S. Patent Application Publication 2023/0090827.

Some image sensing devices of this sort include readout circuits, which are coupled to respective pairs or larger groups of adjacent photodetectors. In full-resolution mode, the readout circuits read out signals individually from each of the photodetectors. When higher sensitivity is desired, the readout circuits bin together the signals from pairs or larger groups of the photodetectors. For purposes of phase detection autofocus (PDAF), the readout circuits may output a difference between the signals generated by adjacent photodetectors in PDAF groups.

At the output from the camera, the mosaic of red, green, and blue raw color pixels is interpolated to reconstruct a full-color (RGB) image, with red, green, and blue intensity values for each pixel. Typically, the resolution and low-light sensitivity of the RGB image depends mainly on the resolution and area of the green color channel. Embodiments of the present invention that are described herein provide novel layouts of the colored tiles in the color filter layer on the photodetector array that enhance the resolution and sensitivity of the resulting image.

In some embodiments, in which the readout circuits are coupled to respective pairs of the photodetectors, both the photodetectors in a first set of the pairs of the photodetectors are overlain by respective green tiles, while in a second set of the pairs, the two photodetectors are overlain by tiles of different colors. For example, in the second set of photodetector pairs, one of the photodetectors may be overlain by a red tile, while the other photodetector is overlain by a blue tile. As another example, in at least some of the pairs in the second set, one of the photodetectors may be overlain by a red or blue tile, while the other photodetector is overlain by a green tile. Typically, the photodetector pairs in the first set are overlain by respective microlenses extending over both photodetectors. These common microlenses enable the green pixels to be conveniently binned and/or used for PDAF. The photodetectors in the second set provide high-resolution red and blue input data.

In some of the embodiments that are described below, the green tiles cumulatively cover more than 50% of the total area of the color filter layer, and possibly at least 75% of the total area. This increased green coverage is in contrast to Bayer-type color image sensors, which typically comprise 50% green and 25% each of red and blue areas. The increased green area in the present embodiments can be applied in enhancing the intensity resolution and low-light sensitivity of the output image, at the expense of lower spatial resolution of the color information in output image.

Although the embodiments described herein are based specifically, for the sake of clarity and concreteness, on color matrices of red, green, and blue tiles, with readout from pairs of adjacent photodetectors, the principles of the present invention may be applied to color filter layers that include other colors, as well as to devices that provide larger or smaller numbers of photodetectors in each readout group. For example, the features of the embodiments described below may be applied, mutatis mutandis, to the sorts of image sensors described in the above-mentioned U.S. Pat. No. 11,563,910 and U.S. Patent Application Publication 2023/0090827, with larger numbers of photodetectors in each group. As another example, the color filter arrays in the embodiments described below may be modified to include clear (white) or gray regions. All such alternative implementations are considered to be within the scope of the present invention.

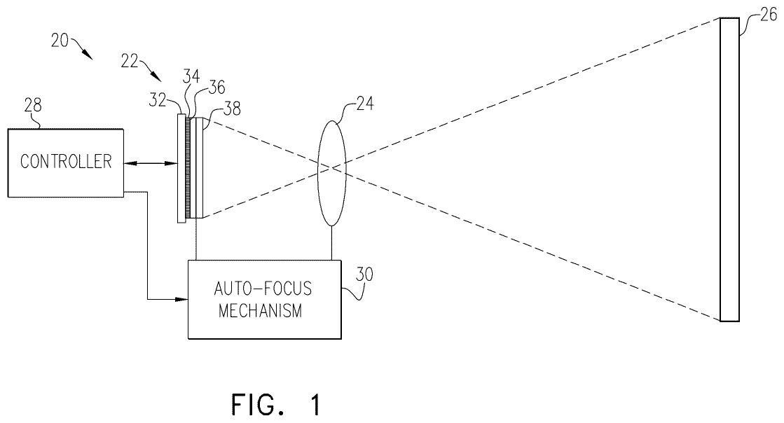

FIG. 1 is a schematic side view of a camera 20 comprising an image sensing device 22 with a novel mosaic filter layout, in accordance with an embodiment of the invention. Objective optics 24 image a target 26 onto image sensing device 22. An autofocus mechanism 30 adjusts a focal property of the objective optics 24, for example by shifting the distance between optics 24 and device 22 or by adjusting the focal length of optics 24, as is known in the art. A controller 28 processes the signals output by PDAF pixels in image sensing device 22 and drives autofocus mechanism 30 in response to these signals so as to form a well-focused image on the image sensing device.

Image sensing device 22 comprises a semiconductor substrate 32, such as a silicon wafer substrate. An array of photodetectors 34, such as silicon photodiodes, is formed on substrate 32 at a predefined pitch, along with suitable switching and readout circuits 35. The photodetectors and associated circuits may be formed using any suitable process of thin film deposition and photolithography, such as a CMOS process. The circuits described in the above-mentioned U.S. Pat. No. 11,563,910, for example, may be adapted for this purpose. A color filter layer 36 is deposited over photodetectors 34, and an array of microlenses 38 is disposed over color filter layer 36. Typically (although not necessarily), microlenses 38 comprise OCLs, which are also formed by a process of material deposition, photolithography, and etching, as is known in the art.

The figures that follow show various configurations of color filter layer 36 and microlenses 38 that may be used in accordance with embodiments of the invention. These figures show only partial views of the color filter matrix and corresponding microlenses, since the entire image sensing device, typically comprising many megapixels, cannot practically be shown in patent drawings.

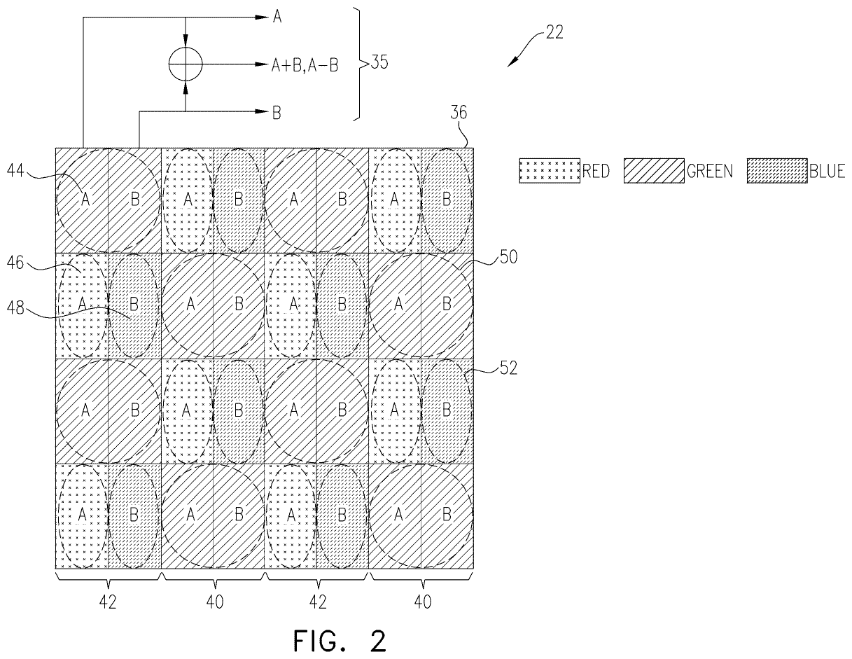

FIG. 2 is a schematic partial frontal view of image sensing device 22, in accordance with an embodiment of the invention. Readout circuits 35 are coupled to respective pairs 40, 42 of photodetectors 34, and are capable of outputting signals from the respective pairs either in an individual mode, in which the signals (A, B) are read out individually from each of the photodetectors, or in a combined mode, in which the signals are binned together pairwise to give sum (A+B) and/or difference (A−B) signals. The summed signals are used to enhance sensitivity in low-light conditions, while the difference signals can be used for PDAF, to drive autofocus mechanism 30. The sets of pairs 40 and 42 of the photodetectors are interleaved in a grid pattern.

Color filter layer 36 comprises a matrix of green tiles 44, red tiles 46, and blue tiles 48, each tile overlying a respective photodetector 34. The pitch of the array of photodetectors 34 is equal to the distance between adjacent gridlines in this and subsequent figures, and tiles 44, 46, 48 have the same pitch as the photodetectors. In the set of pairs 40 of the photodetectors, both the photodetectors are overlain by respective green tiles 44, while in the set of pairs 42 of the photodetectors, one of the photodetectors is overlain by a red tile 46, and the other photodetector is overlain by a blue tile 48. Each of pairs 40 is overlain by a common microlens 50, for example a 1×2 OCL, to enable binning and PDAF functions in the green pixels. On the other hand, within pairs 42, each photodetector is overlain by its own microlens 52 for enhanced resolution in the red and blue pixels.

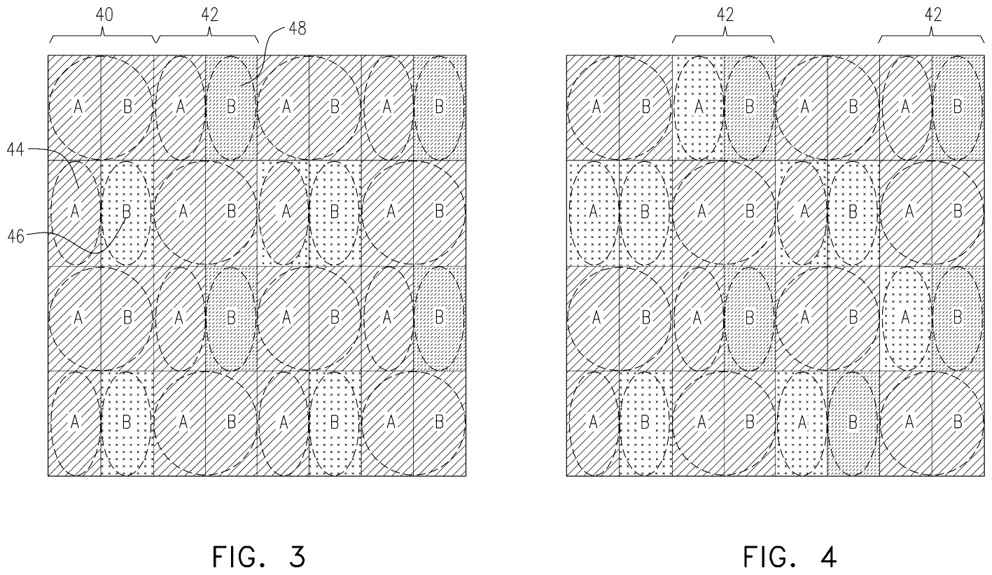

FIG. 3 is a schematic partial frontal view of image sensing device 22, in accordance with another embodiment of the invention. This embodiment is similar to the embodiment of FIG. 2, and the description and numbering of repeated features in this and subsequent embodiments have been omitted for the sake of brevity. In the present embodiment, however, in each of pairs 42 of the photodetectors, one of the photodetectors is overlain by a red tile 46 or a blue tile 48, while the other photodetector is overlain by a green tile 44. In other words, 75% of the total area of color filter layer 36 is covered by green tiles. This configuration enhances the sensitivity and resolution of device 22 in the green range, at the expense of lower resolution and sensitivity to red and blue light.

FIG. 4 is a schematic partial frontal view of image sensing device 22, in accordance with yet another embodiment of the invention. This embodiment combines the features of the two preceding embodiments, in that some of pairs 42 are overlain by one blue tile and one red tile, while other pairs 42 are overlain by a red or blue tile and a green tile. In this case, 62.5% of the total area of color filter layer 36 is covered by green tiles.

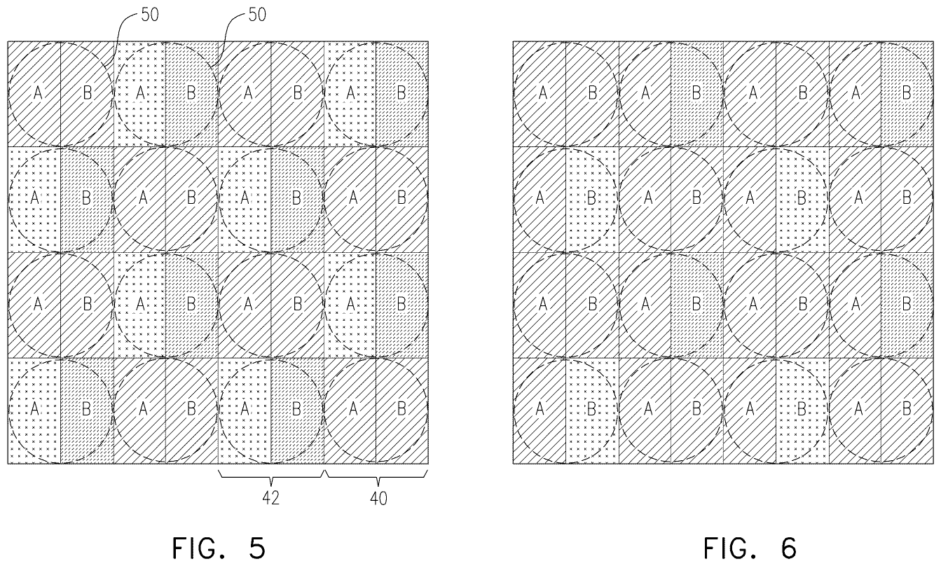

FIG. 5 is a schematic partial frontal view of image sensing device 22, in accordance with an alternative embodiment of the invention. The layout of colored tiles over pairs 40 and 42 of photodetectors in this embodiment is identical to that shown in FIG. 2. In the present embodiment, however, pairs 40 and 42 of the photodetectors are all overlain by respective common microlenses 50, for example 1×2 OCLs. This configuration may be simpler to manufacture than the embodiment of FIG. 2, though possibly at the expense of a small loss of resolution.

FIG. 6 is a schematic partial frontal view of image sensing device 22, in accordance with still another embodiment of the invention. In this embodiment, the layout of colored tiles over pairs 40 and 42 of photodetectors is identical to that shown in FIG. 3. As in the embodiment of FIG. 5, however, pairs 40 and 42 are all overlain by respective common microlenses 50.

FIG. 7 is a schematic partial frontal view of an image sensing device in accordance with a further embodiment of the invention. In this case, all the pairs of photodetectors are overlain by one green tile and a second tile that is either blue or red. Each pair is overlain by a 1×2 OCL. This embodiment applies the enhanced spatial sampling of the red and blue color channels that is shown in FIG. 5 to the green channel, as well. It enables spatial sampling of all color channels with maximal resolution, though at the expense of PDAF and binning capabilities.

In an alternative embodiment (not shown in the figures), different local layouts may be mixed over the area of an image sensing device. For example, some groups of photodetectors may be overlaid by color tiles in the pattern of FIG. 5, while others follow the pattern of FIG. 7. All such mixed layouts are considered to be within the scope of the present invention.

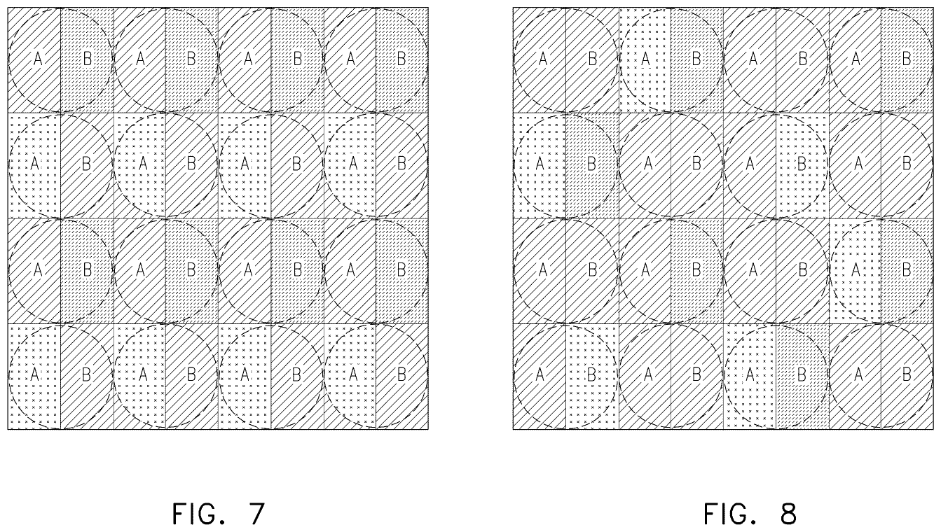

FIG. 8 is a schematic partial frontal view of image sensing device 22, in accordance with yet another embodiment of the invention. In this embodiment, the layout of colored tiles over pairs 40 and 42 of photodetectors is identical to that shown in FIG. 4. As in the embodiments of FIGS. 5 and 6, pairs 40 and 42 are all overlain by respective common microlenses 50.

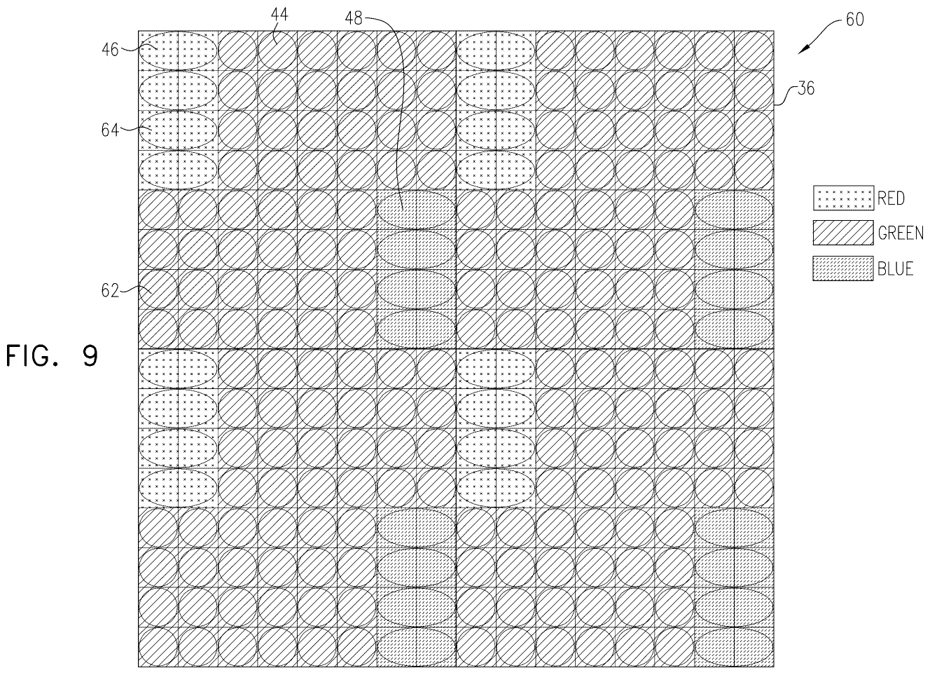

FIG. 9 is a schematic partial frontal view of image sensing device 60, in accordance with another alternative embodiment of the invention. As in the preceding figures, the pitch of the photodetectors in device 60 is equal to the distance between adjacent gridlines. Color filter layer 36 in this embodiment comprises a matrix of green tiles 44, red tiles 46, and blue tiles 48. The green tiles cumulatively cover 75% of the total area of the color filter layer. Microlenses 62, such as 1×1 OCLs, with a transverse dimension no greater than the pitch of the array of photodetectors, overlie all the photodetectors that are covered by green tiles 44. Microlenses 64 with a transverse dimension greater than the pitch, such as 1×2 OCLs, overlie the photodetectors that are covered by red or blue tiles 46, 48.

Each microlens 64 focuses light onto a pair of adjacent red or blue photodetectors, which can thus serve as PDAF pixels. In this manner, the autofocus capability of device 60 is achieved without compromising the resolution of the green channel. Meanwhile, the 1×1 OCLs overlying green tiles 44 enable both maximal resolution of the output images under good lighting conditions and various levels of binning (such as binning over groups of 2×2 or 4×4 photodetectors) to compensate optimally in low-light conditions. The clustering of pixel tiles (or tile pairs) of the same color in this type of layout is beneficial in improving the signal/noise characteristics of binned images.

Although the embodiments described above include particular types and distributions of color filter tiles and microlenses over the area of an image sensing device, the principles of these embodiments may be applied in creating other color tile and microlens patterns, in accordance with the principles of the present invention. It will thus be understood that the embodiments described above are cited by way of example, and the present invention is not limited to what has been particularly shown and described hereinabove. Rather, the scope of the present invention includes both combinations and subcombinations of the various features described hereinabove, as well as variations and modifications thereof which would occur to persons skilled in the art upon reading the foregoing description and which are not disclosed in the prior art.

1. An image sensing device, comprising:
a semiconductor substrate;
a first array of photodetectors disposed on the substrate;
readout circuits, which are disposed on the substrate and coupled to respective pairs of the photodetectors, and which are configured to output signals from the respective pairs in a first mode, in which the signals are read out individually from each of the photodetectors, and in a second mode, in which the signals are binned together pairwise; and
a color filter layer disposed over the photodetectors and comprising a matrix of red, green, and blue tiles, such that in a first set of the pairs of the photodetectors, both the photodetectors are overlain by respective green tiles, while in a second set of the pairs of the photodetectors, one of the photodetectors is overlain by a first tile of a first color, while the other one of the photodetectors is overlain by a second tile of a different, second color.

2. The device according to claim 1, and comprising first microlenses overlying respective pairs of the photodetectors in the first set, and second microlenses overlying the photodetectors in the second set.

3. The device according to claim 2, wherein the pairs of the photodetectors in the first set define phase detection autofocus (PDAF) pixels, and wherein the readout circuits are configured to output a difference between the signals output by the photodetectors in the pairs in the first set.

4. The device according to claim 2, wherein the second microlenses overlie respective pairs of the photodetectors in the second set.

5. The device according to claim 2, wherein each of the second microlenses overlies a single, respective one of the photodetectors.

6. The device according to claim 1, wherein in at least some 4 the pairs in the second set, one of the photodetectors is overlain by a red tile, while the other one of the photodetectors is overlain by a blue tile.

7. The device according to claim 1, wherein in at least some of the pairs in the second set, one of the photodetectors is overlain by a red or blue tile, while the other one of the photodetectors is overlain by a green tile.

8. The device according to claim 1, wherein the green tiles cumulatively cover more than 50% of a total area of the color filter layer.

9. The device according to claim 8, wherein the green tiles cumulatively cover at least 75% of the total area of the color filter layer.

10. The device according to claim 1, wherein the first and second sets of the pairs of the photodetectors are interleaved on the substrate in a grid pattern.

11. An image sensing device, comprising:
a semiconductor substrate;
an array of photodetectors disposed on the substrate; and
a color filter layer disposed over the photodetectors and comprising a matrix of red, green, and blue tiles, such that the green tiles cumulatively cover more than 50% of a total area of the color filter layer.

12. The device according to claim 11, wherein the green tiles cumulatively cover at least 75% of the total area of the color filter layer.

13. The device according to claim 11, and comprising an arrangement of microlenses disposed over the color filter layer and comprising:
first microlenses, which have a first transverse dimension no greater than a pitch of the array of photodetectors and are disposed respectively over all the photodetectors that are covered by the green tiles; and
second microlenses, which have a second transverse dimension greater than the pitch disposed over the photodetectors that are covered by the red and blue tiles, each second microlens being configured to focus light onto two or more of the photodetectors.

14. The device according to claim 13, wherein the two or more of the photodetectors onto which the second microlenses focus the light define phase detection autofocus (PDAF) pixels.

15. A method for image sensing, comprising:
coupling readout circuits to respective pairs of photodetectors in a first array disposed on a semiconductor substrate;
outputting signals by the readout circuits from the respective pairs in a first mode, in which the signals are read out individually from each of the photodetectors, and in a second mode, in which the signals are binned together pairwise; and
overlaying the photodetectors with a color filter layer comprising a matrix of red, green, and blue tiles, such that in a first set of the pairs of the photodetectors, both the photodetectors are overlain by respective green tiles, while in a second set of the pairs of the photodetectors, one of the photodetectors is overlain by a first tile of a first color, while the other one of the photodetectors is overlain by a second tile of a different, second color.

16. The method according to claim 15, and comprising overlaying first microlenses over respective pairs of the photodetectors in the first set, and second microlenses over the photodetectors in the second set.

17. The method according to claim 16, wherein the pairs of the photodetectors in the first set define phase detection autofocus (PDAF) pixels, and wherein outputting the signals comprises outputting a difference between the signals output by the photodetectors in the pairs in the first set.

18. The method according to claim 15, wherein in at least some of the pairs in the second set, one of the photodetectors is overlain by a red tile, while the other one of the photodetectors is overlain by a blue tile.

19. The method according to claim 15, wherein in at least some of the pairs in the second set, one of the photodetectors is overlain by a red or blue tile, while the other one of the photodetectors is overlain by a green tile.

20. The method according to claim 15, wherein the green tiles cumulatively cover more than 50% of a total area of the color filter layer.
